(19) United States
(12) Patent Application Publication
(10) Pub. No.: US 2025/0350276 A1
(43) Pub. Date: Nov. 13, 2025

(54) DRIVER CIRCUIT

(71) Applicant: Winbond Electronics Corp., Taichung City (TW)

(72) Inventors: Shan-Jung Yang, Taichung City (TW); Chieh-Sung Lin, Taichung City (TW)

(73) Assignee: Winbond Electronics Corp., Taichung City (TW)

(21) Appl. No.: 19/183,943

(22) Filed: Apr. 21, 2025

(30) Foreign Application Priority Data
May 13, 2024 (TW) 113117601

(51) Int. Cl. H03K 17/16; G11C 8/08

(52) U.S. Cl. CPC H03K 17/162; G11C 8/08

(57) ABSTRACT

A driver circuit includes a driving transistor and a compensation circuit. A first end of the driving transistor is coupled to an output node. The compensation circuit is coupled to the output node and a second end and a control end of the driving transistor. The compensation circuit is configured to receive a power supply voltage and a reference voltage, perform a compensation operation in response to multiple control signals, and provide a control voltage to the control end of the driving transistor to compensate for a variation of a threshold voltage of the driving transistor.

### CROSS-REFERENCE TO RELATED APPLICATION

This application claims the priority benefit of Taiwan application serial no. 113117601, filed on May 13, 2024. The entirety of the above-mentioned patent application is hereby incorporated by reference herein and made a part of this specification.

### BACKGROUND

### Technical Field

The disclosure relates to an electronic circuit, and more particularly, to a driver circuit.

### Description of Related Art

With the advancement of technology, product applications of some memory devices (including volatile or non-volatile) continue to pursue higher operating speed and density utilization, and sizes of elements continue to shrink. When operating in a high-frequency, high-temperature, and high-pressure environment for a long time, it is easy to increase the speed of degradation for the elements. In particular, a threshold voltage of a transistor inside a driver is prone to variations, causing poor operation of the elements.

### SUMMARY

The disclosure provides a driver circuit, which may compensate for a variation of a threshold voltage of an internal transistor to improve product quality.

A driver circuit in the disclosure includes a driving transistor and a compensation circuit. A first end of the driving transistor is coupled to an output node. The compensation circuit is coupled to the output node and a second end and a control end of the driving transistor. The compensation circuit is configured to receive a power supply voltage and a reference voltage, perform a compensation operation in response to multiple control signals, and provide a control voltage to the control end of the driving transistor to compensate for a variation of a threshold voltage of the driving transistor.

Based on the above, the driver circuit in the disclosure may compensate for the variation of the threshold voltage of the driving transistor when the driving transistor is required to be turned on through the compensation operation. In this way, the impact of degradation of the elements may be reduced, and the product quality and reliability may be improved.

In order for the aforementioned features and advantages of the disclosure to be more comprehensible, embodiments accompanied with drawings are described in detail below.

### BRIEF DESCRIPTION OF THE DRAWINGS

FIG. 1 is a schematic circuit diagram of a driver circuit according to an embodiment of the disclosure.

FIG. 2 is a schematic waveform diagram of a compensation operation according to an embodiment of the disclosure.

FIGS. 3A to 3C are schematic operation diagrams of a compensation operation according to an embodiment of the disclosure.

### DETAILED DESCRIPTION OF DISCLOSED EMBODIMENTS

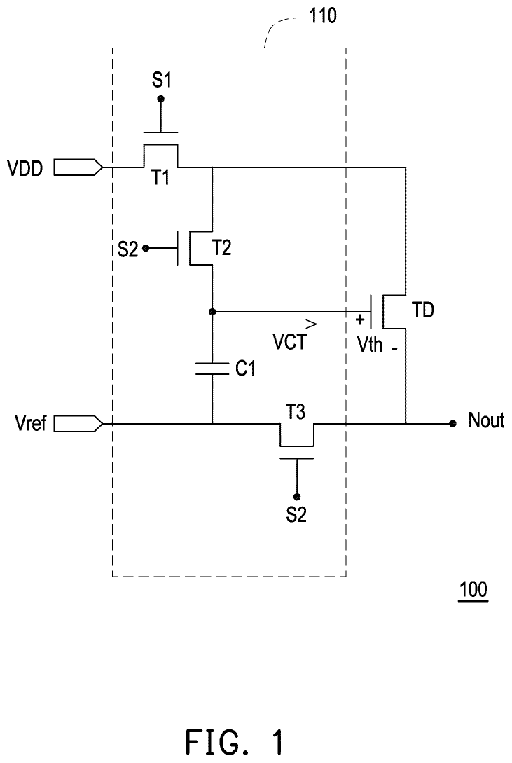

Referring to FIG. 1, a driver circuit 100 according to an embodiment of the disclosure is, for example, a word line driver that may be built into a volatile or non-volatile memory device, which may be used to provide a voltage required by a word line. The driver circuit 100 includes a driving transistor TD and a compensation circuit 110. It should be noted that although the driver circuit 100 in this embodiment is described using the word line driver as an example, the disclosure is not limited thereto. In other embodiments, the driver circuit 100 may also be used to provide a voltage required for data selection or column selection.

In FIG. 1, a first end of the driving transistor TD is coupled to an output node Nout. The compensation circuit 110 is coupled to the output node Nout and a second end and a control end of the driving transistor TD. The compensation circuit 110 may be configured to receive a power supply voltage VDD and a reference voltage Vref. The power supply voltage VDD is, for example, 1.5 to 3.3 volts, and the reference voltage Vref may, for example, vary between a low level value V1 (e.g., a negative voltage) and a high voltage value V2. The output node Nout is further coupled to the word line inside the memory device, for example. When the driving transistor TD is turned on, the driver circuit 100 may provide the power supply voltage VDD to the word line through the output node Nout to select a corresponding memory cell.

The compensation circuit 110 may perform a compensation operation in response to a first control signal S1 and a second control signal S2, and provide a control voltage VCT to the control end of the driving transistor TD to compensate for a variation of a threshold voltage Vth of the driving transistor TD.

Specifically, the compensation circuit 110 has a 3T1C architecture, for example. The compensation circuit 110 includes a first transistor T1, a second transistor T2, a third transistor T3, and s capacitor C1. A first end of the first transistor T1 receives the power supply voltage VDD. A second end of the first transistor T1 is coupled to the second end of the driving transistor TD. A control end of the first transistor T1 receives the first control signal S1. A first end of the second transistor T2 is coupled to the second end of the first transistor T1. A second end of the second transistor T2 is coupled to the control end of the driving transistor TD to provide the control voltage VCT. A control end of the second transistor T2 receives the second control signal S2. A first end of the third transistor T3 receives the reference voltage Vref. A second end of the third transistor T3 is coupled to the output node Nout. A control end of the third transistor T3 receives the second control signal S2. A first end of the capacitor C1 is coupled to the second end of the second transistor T2. A second end of the capacitor C1 is coupled to the first end of the third transistor T3. In this embodiment, the driving transistor TD, the first transistor T1, the second transistor T2, and the third transistor T3 are, for example, N-type metal-oxide-semiconductor field-effect transistors (MOSFET).

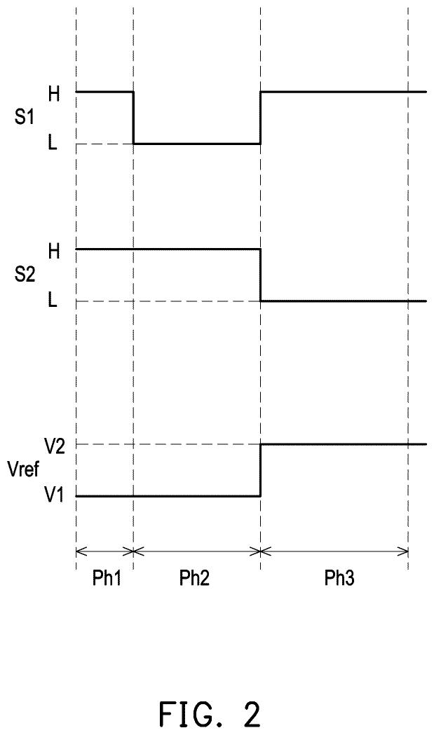

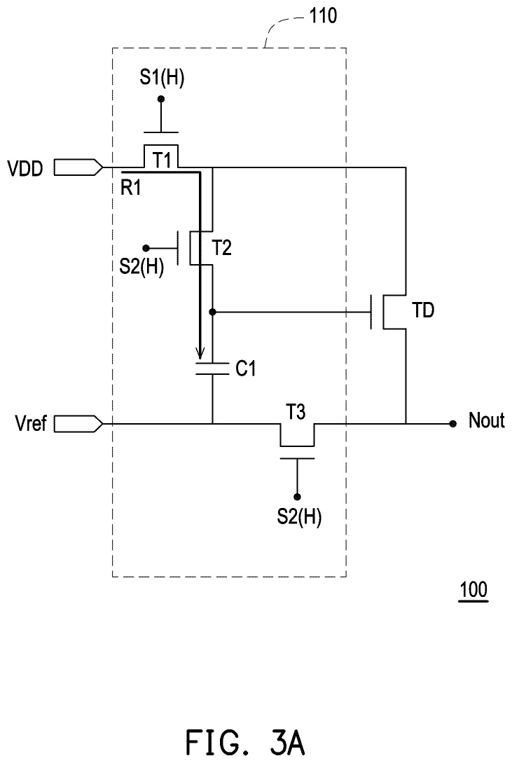

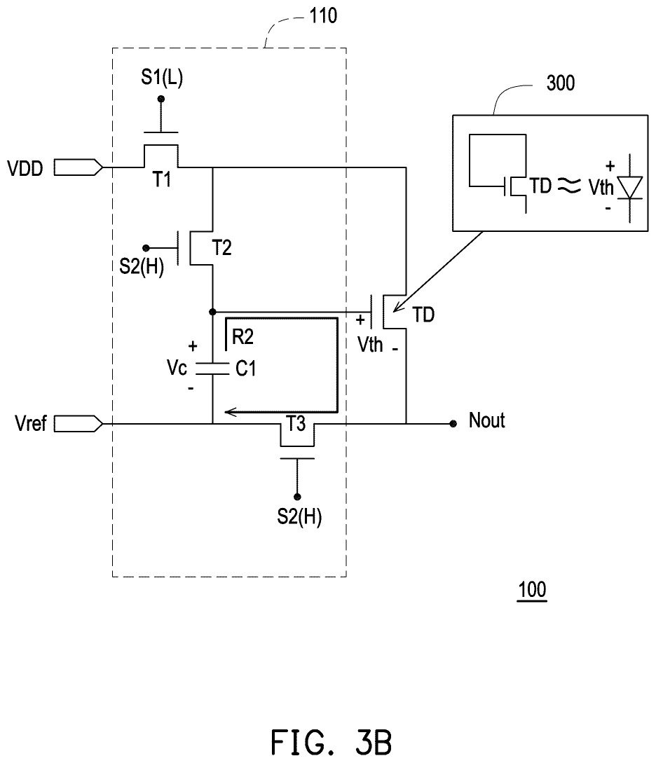

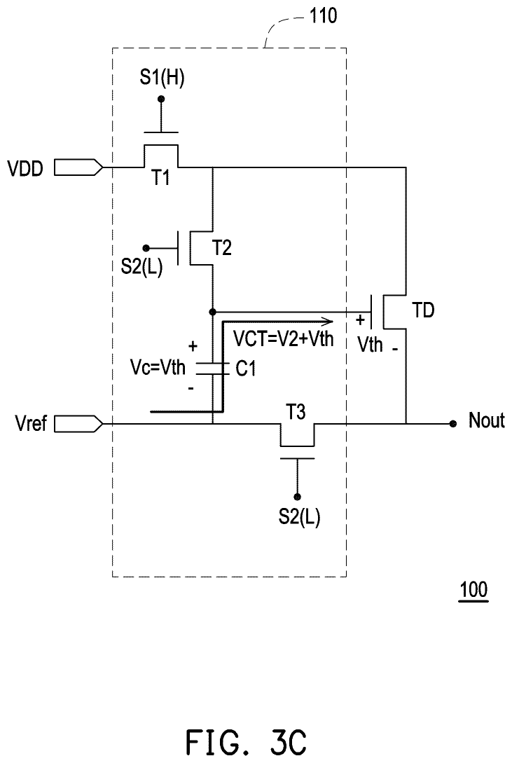

The compensation operation performed by the compensation circuit 110 includes an initial stage Ph1, a sensing stage Ph2, and a compensation stage Ph3 in sequence. FIG. 2 shows voltage waveforms of the first control signal S1, the second control signal S2, and the reference voltage Vref in each of stages such as the initial stage Ph1, the sensing stage Ph2, and the compensation stage Ph3. A vertical axis refers to a voltage value, and a horizontal axis refers to time. The compensation operation performed by the compensation circuit 110 in the disclosure will be described below with reference to FIGS. 3A to 3C.

Referring to both FIGS. 2 and 3A, in the initial stage Ph1, the first control signal S1 and the second control signal S2 are at a first logic level H, and the reference voltage Vref is the low level value V1. At this time, the first transistor T1 is controlled by the first control signal S1 to be turned on, and the second transistor T2 and the third transistor T3 are also controlled by the second control signal S2 to be turned on. Therefore, a charging circuit R1 may be formed in the compensation circuit 110. In this way, in the initial stage Ph1, the capacitor C1 may be charged by the power supply voltage VDD.

In addition, since the reference voltage Vref is the low level value V1 in the initial stage Ph1, even if the third transistor T3 is turned on, it will not have an impact on elements (e.g., the memory cell) at the output node Nout.

Next, referring to both FIGS. 2 and 3B, in the sensing phase Ph2, the first control signal S1 is converted to a second logic level L, the second control signal S2 is still at the first logic level H, and the reference voltage Vref is still the low level value V1. At this time, the first transistor T1 is controlled by the first control signal S1 to be turned off, and the second transistor T2 is controlled by the second control signal S2 to be turned on. Therefore, the driving transistor TD forms an equivalent circuit structure of a diode (as shown in an equivalent circuit 300). Once a voltage at the control end of the driving transistor TD is greater than the threshold voltage Vth, the driving transistor TD will be turned on. At the same time, the third transistor T3 is also controlled by the second control signal S2 to be turned on, thereby forming a discharge circuit R2 in the compensation circuit 110. In this way, in the sensing phase Ph2, the capacitor C1 may be continuously discharged through the discharge circuit R2 until a capacitance voltage Vc between two ends of the capacitor C1 is equivalent to the threshold voltage Vth (Vc=Vth).

Then, referring to both FIGS. 2 and 3C, in the compensation stage Ph3, the first control signal S1 is converted to the first logic level H again, the second control signal S2 is converted to the second logic level L, and the reference voltage Vref is converted to the high voltage value V2. At this time, the first transistor T1 is controlled by the first control signal S1 to be turned on, and the second transistor T2 and the third transistor T3 are controlled by the second control signal S2 to be turned off. Due to coupling characteristics of the capacitor C1, the compensation circuit 110 may generate the control voltage VCT (VCT=V2+Vth) by adding the capacitance voltage Vc (Vc=Vth) between the two ends of the capacitor C1 to the reference voltage Vref (Vref=V2) to turn on the driving transistor TD. In this way, no matter whether the threshold voltage Vth of the driving transistor TD changes or not, an impact of the threshold voltage Vth may be eliminated, so that the reference voltage Vref at the high voltage value V2 may smoothly turn on the driving transistor TD every time, avoiding defects in the operation of the elements.

Through the compensation operation in this embodiment, it is possible to prevent a shift of gate characteristics of a field-effect transistor when operating in a high-frequency, high-temperature, and high-pressure environment for a long time, and reduce an impact of degradation of the elements, thereby improving product quality and reliability.

It should be noted that the first control signal S1, the second control signal S2, and the reference voltage Vref in this embodiment may be provided by a memory controller, for example. The memory controller is, for example, a state machine, a central processing unit, or other programmable general-purpose or special-purpose microprocessors, digital signal processors, programmable controllers, application-specific integrated circuits, programmable logic devices, or other similar devices or a combination of these devices. In addition, the voltage waveforms in FIG. 2 are for a case where the driving transistor TD, the first transistor T1, the second transistor T2, and the third transistor T3 are the N-type metal-oxide-semiconductor field-effect transistors. However, the disclosure is not limited thereto. In other embodiments, those skilled in the art should be able to change the driving transistor TD, the first transistor T1, the second transistor T2, and the third transistor T3 to P-type metal-oxide-semiconductor field-effect transistors to perform the compensation operation according to actual requirements thereof and with reference to teachings in this embodiment.

Based on the above, the driver circuit in the disclosure may compensate for the variation of the threshold voltage of the driving transistor when the power supply voltage is required to be output through the compensation operation. In this way, it is possible to prevent the shift of the gate characteristics of the field-effect transistor when operating in the high-frequency, high-temperature, and high-pressure environment for a long time, and reduce the impact of degradation of the elements, thereby improving the product quality and reliability.

What is claimed is:

1. A driver circuit, comprising:
a driving transistor, wherein a first end thereof is coupled to an output node; and
a compensation circuit coupled to the output node and a second end and a control end of the driving transistor, configured to receive a power supply voltage and a reference voltage, perform a compensation operation in response to a plurality of control signals, and provide a control voltage to the control end of the driving transistor to compensate for a variation of a threshold voltage of the driving transistor.

2. The driver circuit according to claim 1, wherein the control signals comprise a first control signal and a second control signal, and the compensation circuit comprises:
a first transistor, wherein a first end thereof receives the power supply voltage, a second end thereof is coupled to the second end of the driving transistor, and a control end thereof receives the first control signal;
a second transistor, wherein a first end thereof is coupled to the second end of the first transistor, a second end thereof is coupled to the control end of the driving transistor, and a control end thereof receives the second control signal;
a third transistor, wherein a first end thereof receives the reference voltage, a second end thereof is coupled to the output node, and a control end thereof receives the second control signal; and
a capacitor, wherein a first end thereof is coupled to the second end of the second transistor, and a second end thereof is coupled to the first end of the third transistor.

3. The driver circuit according to claim 2, wherein the compensation operation comprises an initial stage, a sensing stage, and a compensation stage in sequence.

4. The driver circuit according to claim 3, wherein in the initial stage, the first control signal and the second control signal are at a first logic level, and the reference voltage is a low voltage value.

5. The driver circuit according to claim 3, wherein in the initial stage, the first transistor is controlled by the first control signal to be turned on, the second transistor and the third transistor are controlled by the second control signal to be turned on, a charging circuit is formed in the compensation circuit, and the capacitor is charged by the power supply voltage.

6. The driver circuit according to claim 3, wherein in the sensing stage, the first control signal is converted to a second logic level, the second control signal is at a first logic level, and the reference voltage is a low voltage value.

7. The driver circuit according to claim 3, wherein in the sensing stage, the first transistor is controlled by the first control signal to be turned off, the second transistor and the third transistor are controlled by the second control signal to be turned on, and a discharge circuit is formed in the compensation circuit, so that the capacitor is continuously discharged until a capacitance voltage between two ends of the capacitor is equivalent to the threshold voltage.

8. The driver circuit according to claim 3, wherein in the compensation stage, the first control signal is converted to a first logic level, the second control signal is converted to a second logic level, and the reference voltage is converted to a high voltage value.

9. The driver circuit according to claim 3, wherein in the compensation stage, the first transistor is controlled by the first control signal to be turned on, the second transistor and the third transistor are controlled by the second control signal to be turned off, and the compensation circuit generates the control voltage by adding a capacitance voltage between two ends of the capacitor to the reference voltage to turn on the driving transistor.

10. The driver circuit according to claim 1, wherein when the driving transistor is turned on, the power supply voltage is provided to a word line through the output node to select a corresponding memory cell.

11. The driver circuit according to claim 2, wherein the first control signal, the second control signal and the reference voltage are provided by a memory controller.

12. The driver circuit according to claim 2, wherein the driving transistor, the first transistor, the second transistor and the third transistor are N-type metal-oxide-semiconductor field-effect transistors.

13. The driver circuit according to claim 2, wherein the driving transistor, the first transistor, the second transistor and the third transistor are P-type metal-oxide-semiconductor field-effect transistors.
